(19) United States
(12) Patent Application Publication
(10) Pub. No.: US 2012/0220066 A1
(43) Pub. Date: Aug. 30, 2012

(54) CZTS/SE PRECURSOR INKS AND METHODS FOR PREPARING CZTS/SE THIN FILMS AND CZTS/SE-BASED PHOTOVOLTAIC CELLS

(75) Inventor: Yanyan Cao, Wilmington, DE (US)

(73) Assignee: E.I. DU PONT DE NEMOURS AND COMPANY, Wilmington, DE (US)

(21) Appl. No.: 13/505,841

(22) PCT Filed: May 21, 2010
(86) PCT No.: PCT/US10/35792

§ 371 Date: May 3, 2012

Related U.S. Application Data
(60) Provisional application No. 61/264,362, filed on Nov. 25, 2009.

(51) Int. Cl. H01L 31/18; H01L 21/31; H01B 1/10

(52) U.S. Cl. 438/73; 252/519.4; 438/778; 257/E31.008; 257/E21.24

(57) ABSTRACT

The present invention relates to coated binary and ternary nanoparticle chalcogenide compositions that can be used as copper zinc tin chalcogenide precursor inks. In addition, this invention provides processes for manufacturing copper zinc tin chalcogenide thin films and photovoltaic cells incorporating such thin films.

### CROSS REFERENCE TO RELATED APPLICATIONS

This application claims priority under 35 U.S.C. §119(e) from U.S. Provisional Application No. 61/264362 filed Nov. 25, 2009 which is incorporated herein in its entirety as a part hereof.

### FIELD OF THE INVENTION

The present invention relates to coated binary and ternary chalcogenide nanoparticle compositions that can be used as copper zinc tin chalcogenide precursor inks. In addition, this invention provides processes for manufacturing copper zinc tin chalcogenide thin films and photovoltaic cells incorporating such thin films.

### BACKGROUND

Thin-film photovoltaic cells typically use semiconductors such as CdTe or copper indium gallium sulfide/selenide (CIGS) as an energy absorber material. Due to the limited availability of indium, alternatives to CIGS are sought. Kesterite (Cu₂ZnSnS₄ or “CZTS”) possesses a band gap energy of about 1.5 eV and a large absorption coefficient (approx. 10⁴ cm⁻¹), making it a promising CIGS replacement. In addition, CZTS contains only non-toxic and abundant elements.

Current techniques to make CZTS thin films (e.g., thermal evaporation, sputtering, hybrid sputtering, pulsed laser deposition and electron beam evaporation) require complicated equipment and therefore tend to be expensive. Electrochemical deposition is an inexpensive process, but compositional non-uniformity and/or the presence of secondary phases prevents this method from generating high quality CZTS thin films. CZTS thin films can also be made by the spray pyrolysis of a solution containing metal salts, typically CuCl, ZnCl₂, SnCl₄, and thiourea as the sulfur source. This method tends to yield films of poor morphology, density and grain size. Photochemical deposition has also been shown to generate p-type CZTS thin films. However, the composition of the product is not well controlled, and it is difficult to avoid the formation of impurities such as hydroxides. Quaternary CZTS precursor powders can be prepared and deposited on a substrate by standard printing techniques. Subsequent annealing in a nitrogen and sulfur atmosphere leads to the formation of CZTS films. However, it is difficult to control the molar ratio of elements in the CZTS powder, which limits the ultimate performance of the CZTS thin film.

The formation of kesterite from uncoated binary and ternary sulfides has also been disclosed.

However, there still exists a need for a process that provides high quality CZTS thin films at a low cost.

### BRIEF DESCRIPTION OF THE FIGURES

FIG. 1 illustrates the XRD pattern of CZTS formed from spin-coated Cu₂SnS₃ and ZnS precursors annealed in a sulfur-rich atmosphere, as described in Example 20.

FIG. 2 illustrates the J-V curves of a solar cell prepared as described in Example 26.

FIG. 3 illustrates the J-V curves of a solar cell prepared as described in Example 27.

FIG. 4 illustrates the J-V curves of a solar cell prepared as described in Example 28.

### DETAILED DESCRIPTION

One aspect of this invention provides nanoparticle compositions that can be used as copper zinc tin chalcogenide precursor inks. The nanoparticle compositions comprise mixtures of binary and/or ternary chalcogenides.

Another aspect of this invention provides coated substrates comprising a substrate and a coating comprising one or more layers comprising mixtures of binary and/or ternary chalcogenides.

Another aspect of this invention provides processes for manufacturing copper zinc tin chalcogenide thin films using the copper zinc tin chalcogenide precursor inks. The copper zinc tin chalcogenide films can be used as absorbers in thin-film photovoltaic cells.

Another aspect of this invention provides processes for using CZTS, CZTSe or CZTS/Se precursor inks to make thin film photovoltaic cells.

Herein, the terms “solar cell” and “photovoltaic cell” are synonymous unless specifically defined otherwise. These terms refer to devices that use semiconductors to convert visible and near-visible light energy into usable electrical energy.

As used herein, the term “chalcogen” refers to Group 16 elements, and the terms “metal chalcogenides” or “chalcogenides” refer to materials that comprise metals and Group 16 elements. Suitable Group 16 elements include sulfur and selenium.

Herein, the term “CZTS” refers to Cu₂ZnSnS₄, “CZTSe” refers to Cu₂ZnSnSe₄, and “CZTS/Se” encompasses all possible combinations of Cu₂ZnSn(S,Se)₄, including Cu₂ZnSnS₄, Cu₂ZnSnSe₄, and Cu₂ZnSnS),Se₄₋ₓ, where 0<x<4. The terms “CZTS,” “CZTSe,” and “CZTS/Se” further encompass copper zinc tin sulfide/selenide semiconductors with fractional stoichiometries, e.g., Cu_{1.94}Zn_{0.63}Sn_{1.3}S₄. That is, the stoichiometry of the elements may vary from strictly 2:1:1:4. Materials designated as CZTS/Se may also contain small amounts of other elements such as sodium.

The term “nanoparticle” is meant to include chalcogenide-containing particles characterized by an average longest dimension of about 1 nm to about 1000 nm, or about 5 nm to about 500 nm, or about 10 nm to about 100 nm. Nanoparticles may be in the shape of spheres, rods, wires, tubes, flakes, whiskers, rings, disks, or prisms.

CZTS/Se Precursor Ink

One aspect of this invention is a CZTS/Se precursor ink comprising:

a) a fluid medium;

b) coated copper-containing chalcogenide nanoparticles, wherein the copper-chalcogenide is selected from the group consisting of copper chalcogenide (e.g., Cu₂S, CuS, Cu₂Se, or CuSe) and copper tin chalcogenide (e.g., Cu₂SnS₃, Cu₄SnS₄, or Cu₂SnSe₃). Here Cu₂S and Cu₂Se refer to Cu_{y}S and Cu_{y}Se, wherein 1.75≦y≦2.1;

c) coated tin-containing chalcogenide nanoparticles, wherein the tin chalcogenide is selected from the group consisting of tin chalcogenide (e.g., SnS₂, SnS, SnSe or SnSe₂) and copper tin chalcogenide (e.g., Cu₂SnS₃, Cu₄SnS₄, or Cu₂SnSe₃); and

d) coated zinc-containing chalcogenide nanoparticles, wherein the zinc chalcogenide is ZnS or ZnSe, and wherein the molar ratio of Cu:Zn:Sn:S/Se of the CZTS/Se precursor ink is about 2:1:1:4.

This ink is referred to as a CZTS/Se precursor ink, as it contains the precursors for forming a CZTS/Se thin film.

The term “coated nanoparticles” used herein refers to binary and ternary chalcogenide nanoparticles that are coated with one or more stabilizing agents selected from the group consisting of alkyl amines, alkyl thiols, trialkylphosphine oxide, trialkylphosphines, alkylphosphonic acids, polyvinylpyrrolidone, polycarboxylates, polyphosphates, polyamines, pyridine, alkylpyridines, peptides comprising cysteine and/or histidine residues, ethanolamines, citrates, thioglycolic acid, oleic acid, and polyethylene glycol. Suitable amines include dodecylamine, tetradecyl amine, hexadecyl amine, octadecyl amine, oleylamine, and trioctyl amine. The stabilizing agent is typically physically and/or chemically adsorbed onto the chalcogenide nanoparticle. All references to “wt %” of the nanoparticles are meant to include the stabilizing agent coating.

Suitable fluid media for the CZTS/Se precursor ink include aromatics, alkanes, nitriles, ethers, ketones, esters, organic halides, alcohols, and mixtures thereof. More specifically, suitable fluid media include chloroform, toluene, p-xylene, dichloromethane, acetonitrile, pyridine, hexane, heptane, octane, acetone, water, ethanol, methanol and mixtures thereof. The fluid medium typically comprises 30-99 wt %, or 50-95 wt %, or 60-90 wt % of the CZTS/Se precursor ink.

In addition to the fluid medium and mixture of binary and/or ternary coated chalcogenide nanoparticles, the precursor ink can optionally further comprise one or more additives selected from the group consisting of dispersants, surfactants, polymers, binders, cross-linking agents, emulsifiers, anti-foaming agents, dryers, fillers, extenders, thickening agents, film conditioners, anti-oxidants, flow agents, leveling agents, and corrosion inhibitors. Typically, the additives comprise less than 20 wt %, or less than 10 wt %, or less than 5 wt %, or less than 2 wt %, or less than 1 wt % of the CZTS/Se precursor ink.

Suitable binders include polymers and oligomers with linear, branched, comb/brush, star, hyperbranched or dendritic structures and those with decomposition temperatures below 200° C. Suitable polymers and oligomers include homo- and co-polymers of polyethers; polylactides; polycarbonates; poly[3-hydroxybutyric acid]; polymethacrylates; poly(methacrylic) copolymers; poly(methacrylic acid); poly(ethylene glycol); poly(lactic acid); poly(DL-lactide/glycolide); poly(propylene carbonate); and poly(ethylene carbonate). If present, the polymeric or oligomeric binder is less than 20 wt %, or less than 10 wt %, or less than 5 wt %, or less than 2 wt %, or less than 1 wt % of the CZTS/Se precursor ink.

Suitable surfactants include siloxy-, fluoryl-, alkyl-, and alkynyl-substituted surfactants. Selection is typically based on observed coating and dispersion quality and the desired adhesion to the substrate. Suitable surfactants include Byk® (Byk Chemie), Zonyl® (DuPont), Triton® (Dow), Surynol® (Air Products), and Dynol® (Air Products) surfactants.

The CZTS/Se precursor ink can also optionally comprise sodium salts and elemental chalcogens. In embodiments where sodium salts and/or elemental chalcogens are added to the CZTS/Se precursor ink, the ink is said to be “doped” with these additives. If present, the chalcogen is typically between 0.1 wt % and 10 wt % of the CZTS/Se precursor ink.

In one embodiment, the CZTS/Se precursor ink is prepared by dispersing in a fluid medium a mixture comprising the coated copper-containing, tin-containing, and zinc-containing nanoparticles. In one embodiment, the CZTS precursor ink comprises coated Cu₂SnS₃ and ZnS nanoparticles in about a 1:1.4 molar ratio. In one embodiment, the CZTS precursor ink comprises coated CuS, ZnS and SnS nanoparticles in about a 2:1:1 molar ratio.

The dispersion of the coated nanoparticles in the fluid medium can be aided by agitation or sonication.

Synthesis of Coated Binary and Ternary Chalcogenide Nanoparticles

The coated nanoparticles used in the CZTS/Se precursor ink can be synthesized by methods known in the art, including coprecipitation from solution, microemulsion, sol-gel processing, templated synthesis, and solvothermal methods.

Coated Binary Chalcogenide Nanoparticles

Coated binary chalcogenide nanoparticles, including CuS, CuSe, ZnS, ZnSe and SnS, can be prepared from the corresponding metal salt by reaction of the metal salt with a source of sulfide or selenide in the presence of one or more stabilizing agents at a temperature between 0° C. and 500° C., or between 150° C. and 350° C. The binary chalcogenide nanoparticles can be isolated, for example, by precipitation by a non-solvent followed by centrifugation, and can be further purified by washing, or dissolving and re-precipitating. Suitable metal salts for this synthetic route include Cu(I), Cu(II), Zn(II), Sn(II) and Sn(IV) halides, acetates, nitrates, and 2,4-pentanedionates. Suitable chalcogen sources include elemental sulfur, elemental selenium, Na₂S. Na₂Se, thiourea, and thioacetamide. Suitable stabilizing agents include dodecylamine, tetradecyl amine, hexadecyl amine, octadecyl amine, oleylamine, trioctyl amine, trioctylphosphine oxide, other trialkylphosphine oxides, and trialkylphosphines.

Cu₂S nanoparticles can be synthesized by a solvothermal process, in which the metal salt is dissolved in deionized water. A long-chain alkyl thiol or selenol (e.g., 1-dodecanethiol or 1-dodecaneselenol) can serve as both the sulfur source and a dispersant for nanoparticles. Some additional ligands, including acetate and chloride, can be added in the form of an acid or a salt. The reaction is typically conducted at a temperature between 150° C. and 300° C. and at a pressure between 150 psig and 250 psig nitrogen. After cooling, the product can be isolated from the non-aqueous phase, for example, by precipitation using a non-solvent and filtration.

The binary chalcogenide nanoparticles can also be synthesized by an alternative solvothermal process in which the corresponding metal salt is dispersed along with thioacetamide, thiourea, selenoacetamide, selenourea or other source of sulfide or selenide ions and an organic stabilizing agent (e.g., a long-chain alkyl thiol or a long-chain alkyl amine) in a suitable solvent at a temperature between 150° C. and 300° C. The reaction is typically conducted at a pressure between 150 psig and 250 psig nitrogen. Suitable metal salts for this synthetic route include Cu/I), Cu(II), Zn(II), Sn(II) and Sn(IV) halides, acetates, nitrates, and 2,4-pentanedionates.

The resultant binary chalcogenide nanoparticles obtained from any of the three routes are coated with the organic stabilizing agent(s), as can be determined by secondary ion mass spectrometry and nuclear magnetic resonance spectroscopy. The structure of the inorganic crystalline core of the coated binary nanoparticles obtained can be determined by X-ray diffraction (XRD) and transmission electron microscopy (TEM) techniques.

Coated Ternary Chalcoqenide Nanoparticles

Coated ternary chalcogenide nanoparticles containing two metals, e.g., Cu₂SnS₃, Cu₄SnS₄, or Cu₂SnSe₃ nanoparticles, can be prepared by reacting the corresponding metal salts and chalcogen in the presence of an amine and a second organic stabilizing agent at a temperature between 150° C. and 350° C. Suitable amines include dodecylamine, tetradecyl amine, hexadecyl amine, octadecyl amine, oleylamine, and trioctyl amine.

Alternatively, coated ternary chalcogenide nanoparticles can be synthesized by a solvothermal process in which the corresponding metal salts are dispersed along with a source of sulfide or selenide ions and a long-chain alkyl thiol in a suitable solvent at a temperature between 150° C. and 300° C. Suitable sources of sulfide ions include thioacetamide, thiourea, selenoacetamide and selenourea. Long-chain alkyl thiols include 1-dodecanethiol and 1-decanethiol. The reaction is typically conducted under 175 psig to 275 psig nitrogen.

The resultant ternary chalcogenide nanoparticles obtained from either route are coated with the organic stabilizing agent(s), as can be determined by secondary ion mass spectrometry and nuclear magnetic resonance spectroscopy. The structure of the inorganic core of the coated nanoparticles obtained can be determined by X-ray diffraction (XRD) spectroscopy and tunnel electron microscopy (TEM) techniques.

Exchange of Stabilizing Agents

Prior to formation of the CZTS/Se precursor ink, the coated binary and ternary chalcogenide nanoparticles can be further treated with an alternative stabilizing agent to replace the initial stabilizing agent(S)with the alternative stabilizing agent. This exchange can be carried out by suspending the initially formed coated nanoparticles in a fluid medium in the presence of the alternative stabilizing agent, heating the dispersion, followed by cooling and isolation of the coated nanoparticles. The nanoparticles obtained are coated with the alternative stabilizing agent.

In some embodiments, the initial stabilizing agent is replaced with an alternative stabilizing agent of lower molecular weight, higher volatility or lower decomposition temperature. Use of such alternative stabilizing agents as coating for the mixtures of coated nanoparticle chalcogenides may lead to annealed CZTS/Se films of higher purity and consequently better semiconductor properties. It is believed that CZTS/Se films with lower levels of carbon impurities derived from the stabilizing agent(s) are desirable. Suitable alternative stabilizing agents include pyridine, pyrrolidone, methylpyridine, ethylpyridine, 2-mercaptopyridine, thiophene-2-ethylamine, tetramethylethylenediamine and t-butylpyridine.

Coated Substrate Comprising a CZTS/Se Precursor Ink

In another aspect of the invention, the CZTS/Se precursor ink is deposited on a surface of a substrate by any of several conventional coating techniques, e.g., spin-coating, doctor blade coating, spraying, dip-coating, rod-coating, drop-cast coating, wet coating, printing, roller coating, slot-die coating, meyer bar coating, capillary coating, ink-jet printing, or draw-down coating. The fluid medium can be removed by drying in air or vacuum to form a coated substrate. The drying step can be a separate, distinct step, or can occur as the substrate and precursor ink are heated in an annealing step.

Suitable substrate materials include glass, metal or polymer substrates. The substrate can be rigid or flexible. Of particular interest are substrates of molybdenum-coated soda-lime glass, molybdenum-coated polyimide films, or molybdenum-coated polyimide films with a thin layer of a sodium compound (e.g., NaF, Na₂S, or Na₂Se). Other suitable substrates include solar glass, low-iron glass, green glass, steel, stainless steel, aluminum, ceramics, metalized ceramic plates, metalized polymer plates, and metalized glass plates.

Formation of CZTS/Se Films

In another aspect of the invention, the coated substrate is heated at 400° C. to 800° C., or at 500° C. to 575° C., to obtain an annealed CZTS/Se thin film on the substrate. The annealing step serves to remove substantially all of any water and/or organic species present in the CZTS/Se precursor ink. The annealing step also facilitates the formation of a CZTS/Se thin film through the solid-state reaction of the coated binary and ternary chalcogenide nanoparticles.

The annealing step can include thermal processing, pulsed thermal processing, laser beam exposure, heating via IR lamps, electron beam exposure, and combinations thereof.

The annealing temperature can be modulated to oscillate within a temperature range without being maintained at a particular plateau temperature. This technique is sometimes referred to a “rapid thermal annealing” or “RTA.”

In one embodiment, the film is annealed in a sulfur-rich environment, e.g., a sulfur/N₂ environment. For example, if the annealing is carried out in a tube furnace, nitrogen can be used as a carrier gas, flowing over sulfur, to create a sulfur-rich atmosphere. In one embodiment, the film is annealed in a selenium-rich environment, e.g., a Se/N₂ environment. For example, if the annealing is carried out in a tube furnace, nitrogen can be used as a carrier gas, flowing over selenium, to create a selenium-rich atmosphere. In another embodiment, the film is annealed in a hydrogen sulfide (H₂S)-rich atmosphere. For example, H₂S and nitrogen can be mixed at a volume ratio of 1:9 to create an H₂S-rich atmosphere.

In one embodiment, multiple cycles of coating with a CZTS/Se precursor ink and annealing are carried out to form a thicker CZTS/Se layer on the substrate.

The annealed film typically has an increased density and/or reduced thickness versus that of the wet precursor layer, since the fluid medium and other organic materials have been removed during processing. In one embodiment, the film is between about 0.5 microns and about 5 microns, or between about 1.5 microns and about 2.25 microns, thick.

Preparation of Thin-Film Photovoltaic Cells

Another aspect of this invention provides a process for manufacturing thin-film photovoltaic cells.

A typical photovoltaic cell includes a substrate (e.g., soda-lime glass), a back contact layer (e.g., molybdenum), an absorber layer (also referred to as the first semiconductor layer), a buffer layer (also referred to as the second semiconductor layer, which is typically selected from CdS, Zn (S, O, OH), cadmium zinc sulfides, In(OH)₃, In₂S₃, ZnSe, zinc indium selenides, indium selenides, zinc magnesium oxides, or SnO₂), and a top contact layer (e.g., zinc oxide doped with aluminum). The photovoltaic cell can also include an electrical contact or electrode pad on the top contact layer, and an anti-reflective (AR) coating on the front (light-facing) surface of the substrate to enhance the transmission of light into the semiconductor layer.

One aspect of this invention provides processes for forming photovoltaic cells comprising:

a) coating a photovoltaic cell substrate with a composition comprising:
i) a fluid medium;
ii) coated copper-containing chalcogenide nanoparticles;
iii) coated tin-containing chalcogenide nanoparticles; and
iv) coated zinc-containing chalcogenide nanoparticles,

wherein the chalcogenide is a sulfide or selenide and the molar ratio of Cu:Zn:Sn:S/Se of the composition is about 2:1:1:4 to form a coated substrate;

b) heating the coated photovoltaic cell substrate at a temperature between 400° and 800° to form an annealed CZTS/Se thin film on the photovoltaic cell substrate;

c) optionally repeating steps a) and b) to form a CZTS/Se film of the desired thickness;

d) depositing a buffer layer onto the CZTS/Se layer; and

e) depositing a top contact layer onto the buffer layer.

Suitable substrate materials for the photovoltaic cell substrate include glass, metals, and polymers. The substrate can be rigid or flexible. If the substrate material is glass or plastic, the substrate further comprises a metal coating or metal layer. Suitable substrate materials include soda-lime glass, polyimide films, solar glass, low-iron glass, green glass, steel, stainless steel, aluminum, and ceramics. Suitable photovoltaic cell substrates include molybdenum-coated soda-lime glass, molybdenum-coated polyimide films, molybdenum-coated polyimide films with a thin layer of a sodium compound (e.g., NaF, Na₂S, or Na₂Se), metalized ceramic plates, metalized polymer plates, and metalized glass plates. The photovoltaic cell substrate can also comprise an interfacial layer to promote adhesion between the substrate material and metal layer. Suitable interfacial layers can comprise metals (e.g., V, W, Cr), glass, or compounds of nitrides, oxides, and/or carbides.

Typical photovoltaic cell substrates are glass or plastic, coated on one side with a conductive material, e.g., a metal. In one embodiment, the substrate is molybdenum-coated glass.

Depositing and annealing the CZTS/Se layer on the photovoltaic cell substrate can be carried out as described above.

The buffer layer typically comprises an inorganic material such as CdS, ZnS, zinc hydroxide, Zn (S, O, OH), cadmium zinc sulfides, In(OH)₃, In₂S₃, ZnSe, zinc indium selenides, indium selenides, zinc magnesium oxides, or n-type organic materials, or combinations thereof. Layers of these materials can be deposited by chemical bath deposition, atomic layer deposition, co-evaporation, sputtering or chemical surface deposition to a thickness of about 2 nm to about 1000 nm, or from about 5 nm to about 500 nm, or from about 10 nm to about 300 nm, or 40 nm to 100 nm, or 50 nm to 80 nm.

The top contact layer is typically a transparent conducting oxide, e.g., zinc oxide, aluminum-doped zinc oxide, indium tin oxide, or cadmium stannate. Suitable deposition techniques include sputtering, evaporation, chemical bath deposition, electroplating, chemical vapor deposition, physical vapor deposition, and atomic layer deposition. Alternatively, the top contact layer can comprise a transparent conductive polymeric layer, e.g., poly-3,4-ethylenedioxythiophene (PEDOT) doped with poly(styrenesulfonate) (PSS), which can be deposited by standard methods, including spin coating, dip-coating or spray coating. In some embodiments, the PEDOT is treated to remove acidic components to reduce the potential of acid-induced degradation of the photovoltaic cell components.

In one embodiment, the photovoltaic cell substrate coated with a CZTS/Se film is placed in a cadmium sulfide bath to deposit a layer of CdS. Alternatively, CdS can be deposited on the CZTS/Se film by placing the CZTS/Se coated substrate in a cadmium iodide bath containing thiourea.

In one embodiment, the photovoltaic cell is fabricated using a sputtered layer of insulating zinc oxide in place of CdS. In some embodiments, CdS and ZnO layers are both present in the photovoltaic cell; in other embodiments, only one of CdS and ZnO is present.

In some embodiments, a layer of a sodium compound (e.g., NaF, Na₂S, or Na₂Se) is formed above and/or below the CZTS/Se layer. The layer of the sodium compound can be applied by sputtering, evaporation, chemical bath deposition, electroplating, sol-gel based coatings, spray coating, chemical vapor deposition, physical vapor deposition, or atomic layer deposition.

One advantage of using mixtures of coated nanoparticle chalcogenides to form the precursor ink is that the coated nanoparticle chalcogenides are easily prepared. Another advantage is that the mixtures form stable dispersions that can be stored for long periods without settling or agglomeration of particles. Another advantage is that the overall ratios of copper, zinc, tin and chalcogenide in the precursor ink can be easily varied to achieve optimum performance of the photovoltaic cell. Another advantage is that the nanoparticle mixtures can be annealed at lower temperature than mixtures of larger particles, allowing the use of a wider range of substrates for the photovoltaic cells. Another advantage is that the dense packing of the nanoparticles leads a dense and smooth film, which is hard to achieve with larger particles.

### EXAMPLES

### General

All metal salts and reagents were obtained from commercial sources, and used as received, unless otherwise noted.

“Polyvinylpyrrolidone K30” is polyvinylpyrrolidone with an average molecular weight of 40,000 and was obtained from Fluka Chemical Corp. (Milwaukee, Wis.).

The performance of these thin-film solar cells based on Cu₂ZnSnS₄ (CZTS) films prepared by the methods mentioned above was tested under simulated solar illumination using an Oriel solar simulator from Newport Corporation (Irvine, Calif.) and a E5270 source measuring unit from Agilent Technologies (Santa Clara, Calif.).

### Example 1

This example illustrates a process for synthesizing coated ZnS nanoparticles.

A solution of ZnCl₂ (0.2726 g, 2 mmol) and trioctylphosphine oxide (2.3 g, 5.95 mmol) in 10 mL oleyl amine was heated at 170° C. under a nitrogen atmosphere with continuous mechanical stirring for 1 h. The reaction mixture was cooled to room temperature, followed by the rapid addition of sulfur (0.1924 g, 6 mmol) dissolved in 2.5 mL of oleyl amine.

The reaction mixture was heated and maintained at 320° C. for 1 h. The reaction mixture was cooled, and then ethanol (15 mL) was added to precipitate the coated ZnS nanoparticles, which were collected via centrifugation. The nanoparticles thus obtained were washed through a few cycles of re-suspension in ethanol and centrifugation. The ZnS sphalerite structure was determined by XRD. The particle shape and size were determined using SEM.

### Example 2

This example illustrates a solvothermal process for synthesizing coated Cu₂S nanoparticles.

A solution of copper nitrate (Cu(NO₃)₂.2.5H₂O, 0.2299 g, 1 mmol), sodium acetate (0.8203 g, 10 mmol), and glacial acetic acid (0.6 mL) in 20 mL water was mixed with 1-dodecanethiol (3 mL) at room temperature, in a 400 mL glass-lined Hastelloy C shaker tube. The reaction mixture was heated at 200° C. under 250 psig of nitrogen, for 6 h. The reaction mixture was cooled and the colorless aqueous phase at the bottom of the tube was discarded. Ethanol (20 mL) was added to the dark brown oil phase to precipitate the coated nanoparticles, which were collected via centrifugation. XRD and TEM were used to determine the structure of the nanoparticles obtained. The coated Cu₂S nanoparticles are roughly spherical, with an average diameter of 10-15 nm.

### Example 3

This example illustrates an alternative process for synthesizing coated CuS nanoparticles.

A solution of copper chloride (0.2689 g, 2 mmol) and trioctylphosphine oxide (2.3 g, 5.95 mmol) in 10 mL of oleyl amine was heated at 170° C. under a nitrogen atmosphere with continuous mechanical stirring for 1 h, followed by the rapid addition of sulfur (0.0704 g, 2.2 mmol) dissolved in 2.5 mL of oleyl amine. The reaction mixture was maintained at 170° C. for 30 min before rapid cooling in water and acetone/dry ice baths. The reaction vessel was first submerged in a room temperature water bath and then an acetone-dry ice bath (−78° C.). Ethanol (80 mL) was added to precipitate the coated nanoparticles, which were collected via centrifugation. The nanoparticles were washed through a few cycles of re-suspension in ethanol and centrifugation. The CuS covellite structure was determined by XRD.

### Example 4

This example illustrates a process for synthesizing coated SnS nanoparticles.

A solution of tin chloride (2.605 g, 10 mmol) and trioctylphosphine oxide (11.6 g, 30 mmol) in 40 mL oleyl amine was heated at 210° C. under a nitrogen atmosphere with continuous mechanical stirring for 15 min, followed by the rapid addition of sulfur (0.3840 g, 12 mmol) dissolved in 10 mL oleyl amine. The reaction mixture was maintained at 210° C. for 20 min. Then the reaction temperature was raised to and maintained at 250° C. for 20 min. The reaction mixture was cooled down in a room-temperature water bath. Mixed hexane and ethanol (1:7 hexane:ethanol) was added to the reaction mixture to precipitate the nanoparticles and wash them. XRD analysis showed that SnS was the major product. A minor amount of SnS₂ was also present.

### Example 5

This example illustrates a coprecipitation process for synthesizing coated Cu₂SnS₃ nanoparticles.

A solution of CuCl (0.1980 g, 2 mmol), SnCl₄ (0.2605 g, 1 mmol), and trioctylphosphine oxide (2.3 g, 5.95 mmol) in 10 mL of oleyl amine was heated at 240° C. under a nitrogen atmosphere with continuous mechanical stirring for 15 min, followed by the addition of sulfur (0.0960 g, 3 mmol) dissolved in 3 mL of oleyl amine. The reaction mixture was stirred at 240° C. for 20 minutes. To cool the reaction mixture rapidly, the reaction vessel was first submerged in a room temperature water bath and then an acetone-dry ice bath (−78° C.) to obtain a solid product. The solid was dissolved in hexane and precipitated in ethanol. The precipitated solid was collected using centrifugation. The process of dissolving in hexane, precipitation with ethanol and centrifugation was repeated twice. The Cu₂SnS₃ structure was determined by XRD. Particle shape and size were determined using SEM and TEM.

### Example 6

This example illustrates a solvothermal process for synthesizing coated Cu₂SnS₃ nanoparticles.

To a solution of copper chloride dihydrate (CuCl₂.2H₂O, 0.3466 g, 2 mmol), tin chloride pentahydrate (SnCl₄.5H₂O, 0.3564 g, 1 mmol), and thioacetamide (0.2291 g, 3 mmol) in N, N-dimethylformamide (45 mL), was added 1-dodecanethiol (3 mL). The reaction mixture was stirred vigorously at room temperature for 30 min, then transferred into a glass-lined Hastelloy C shaker tube. The reaction mixture was heated at 180° C. under 250 psig of nitrogen for 12 h. A black product was collected by filtration and dissolved in chloroform. Cu₂SnS₃ nanoparticles were precipitated from the solution with methanol. The Cu₂SnS₃ structure was determined by XRD.

### Example 7

This example illustrates a process for exchanging the stabilizing agents of coated nanoparticles with t-butyl pyridine.

Coated nanoparticles obtained from Example 1 were suspended in t-butyl pyridine and heated at 120° C. for 4 h. The suspension was cooled and stirred at room temperature overnight, followed by centrifugation. The pellet obtained was mixed with t-butyl pyridine and heated at 120° C. for 4 h. The dispersion was then cooled down and stirred at room temperature overnight. The resulting solution was passed through a 0.2 micron syringe filter and the filtrate was dried in a vacuum oven. The dried solid was collected and washed with hexane then dried in a vacuum desiccator to obtain t-butyl-pyridine-coated nanoparticles.

This procedure was repeated for each of the coated nanoparticle products obtained from Examples 2-6.

### Example 8

This example illustrates a process for exchanging the stabilizing agents of coated nanoparticles with pyridine.

Coated nanoparticles (1 g) obtained from Example 1 were suspended in 20 mL pyridine and refluxed in pyridine for 7 h. The suspension was then cooled to room temperature. Hexane (80 mL) was added to precipitate the pyridine-coated nanoparticles, which were then collected by centrifugation and decanting of the supernatant.

The procedure was repeated for each of the coated nanoparticle products obtained from Examples 2-6.

### Examples 9-13

Examples 9 to 13 illustrate the preparations of CZTS precursor inks using coated Cu₂SnS₃ and coated ZnS nanoparticles.

### Example 9

A CZTS precursor ink was prepared by dispersing coated Cu₂SnS₃ nanoparticles and coated ZnS nanoparticles in a 1:1.4 molar ratio in toluene. A dispersion of Cu₂SnS₃ (as obtained from Example 5, 268 mg) and ZnS (as obtained from Example 1, 107 mg) in 1125 mg of toluene was sonicated for 30 min to provide the CZTS precursor ink.

### Example 10

A sonicated solution of coated Cu₂SnS₃ nanoparticles (as obtained from Example 5, 0.4 g) in 40 mL of chloroform was filtered through a 0.45 micron filter to remove aggregates and other large particles. A portion of the filtrate (1 mL, Filtrate A) was dried to determine the concentration of coated Cu₂SnS₃ nanoparticles in the filtrate.

A sonicated solution of coated ZnS nanoparticles (as obtained from Example 1, 0.2 g) in 20 mL of chloroform was filtered through a 0.2 micron filter. A portion of the filtrate (1 mL, Filtrate B) was dried to determine the concentration of coated ZnS nanoparticles in the filtrate.

TABLE 1
Concentration of binary/ternary nanoparticles after filtration

| | Amount of solid | Solid | |
|---|---|---|---|
| | in 1 mL | concentration | |
| | suspension | (mmol/mL) | Wt % |
| Filtrate A | 5.9 mg | 0.017 | 0.4 |
| Filtrate B | 8.1 mg | 0.083 | 0.5 |

Filtrate A (35 mL) was mixed with Filtrate B (7.3 mL) to obtain a CZTS precursor ink, with a 1:1 molar ratio of Cu₂SnS₃: ZnS.

### Example 11

This example illustrates the preparation of a CZTS precursor ink with added polyvinylpyrrolidone K30.

Polyvinylpyrrolidone K30 (1 g) was dissolved in chloroform (99 g) to make a 1 wt % stock solution. Coated Cu₂SnS₃ nanoparticles (as prepared in Example 5, 0.3 g) and coated ZnS nanoparticles (as prepared in Example 1, 0.09 g) were suspended in 1.54 g of the stock solution of polyvinylpyrrolidone K30 in chloroform to provide a dispersion of Cu₂SnS₃ and ZnS in a 1:1 molar ratio. The dispersion was sonicated for 10 min before it was used for coating substrates.

### Example 12

This example illustrates the preparation of a CZTS precursor ink with coated CuS, ZnS and SnS nanoparticles.

To make a 0.33% (by weight) solution of CuS:ZnS:SnS in the molar ratio of 2:1:1, coated CuS nanoparticles (as obtained from Example 3, 12.8 mg), coated ZnS nanoparticles (as obtained from Example 1, 6.5 mg), and coated SnS nanoparticles (as obtained from Example 4, 10.1 mg) were dispersed in 6 mL of chloroform. The dispersion was sonicated (10 min, ice bath) to obtain a CZTS precursor ink.

### Example 13

Coated Cu₂SnS₃ and ZnS nanoparticles, prepared as described in Example 8, are mixed in the molar ratio of 1:1.4. Pyridine (900 mg) is added to 100 mg of this nanoparticle mixture. After sonicating for 10 minutes, an ink is formed which contains Cu₂SnS₃ and ZnS nanoparticles dispersed in pyridine.

### Examples 14-19

Examples 14-18 illustrate the preparation of CZTS precursor films.

### Example 14

This example illustrates the use of spray-coating to deposit CZTS precursor ink onto a substrate and annealing steps to form CZTS films.

The precursor ink obtained from Example 10 was sprayed onto a pre-cleaned molybdenum-coated soda lime glass substrate using an ultrasonic atomizing nozzle (IMPACT 48 from Sono-Tek Corporation, Milton, N.Y.) and the spray-coating profile shown in Table 2. Each coat consisted of 20 passes moving at a speed of 2400 mm/s. A total of 45 coats were applied. After every three coats, the coated substrate was annealed at 550° C. for 1 minute. The final annealing step was carried out at 550° C. for 10 minutes.

The final film thickness was 2830 nm as measured using a profilometer.

TABLE 2
Spray-coating profile

| | |
|---|---|
| Flow rate (mL/min) | 2 |
| Ultrasonic generator power (W) | 1.5 |
| Nitrogen flow (LPM) | 7 |
| Nozzle-to-platter height (inches) | 2 |

### Example 15

This example illustrates the use of spin-coating to deposit CZTS precursor inks onto a substrate.

A CZTS precursor ink obtained from Example 9 was spun-coated onto a molybdenum-coated glass substrate. The ink was applied to the substrate while the substrate was being spun at 200 rpm, then the spinning was continued for 40 sec at 400 rpm. The coated substrate was then put on a hot-plate for a soft-bake (5 min, 75° C.).

### Example 16

This example illustrates the use of rod-coating to deposit CZTS precursor inks onto a substrate.

A CZTS precursor ink obtained from Example 11 was coated onto a glass substrate with a Meyer Rod. An excess of the ink was deposited onto the substrate. The Meyer Rod was passed over the substrate, leaving a uniformly thick layer of ink on the substrate. Solvent was removed by drying the coated substrate in air.

In some instances, a molybdenum-coated glass substrate was used in place of the glass substrate.

### Example 17

This example illustrates the use of drip-coating to deposit CZTS precursor inks onto a substrate.

A CZTS precursor ink obtained from Example 11 was dripped onto a glass substrate and allowed to dry in air to give a coated substrate.

In some instances, a molybdenum-coated glass substrate was used in place of the glass substrate.

### Example 18

This example illustrates the use of drip-coating to deposit CZTS precursor inks containing coated nanoparticles of CuS, ZnS and SnS onto a substrate.

A CZTS precursor ink obtained from Example 12 was dripped onto a glass substrate and allowed to dry in air to give a coated substrate.

In some instances, a molybdenum-coated glass substrate was used in place of the glass substrate.

### Example 19

This example illustrates the use of drip-coating to deposit CZTS precursor inks containing pyridine-stabilized Cu₂SnS₃ and ZnS nanoparticles onto a substrate.

A CZTS precursor ink described in Example 13 is dropped onto glass substrates or molybdenum-coated glass substrates and allowed to dry in air.

### Examples 20-25

Examples 20-25 illustrate annealing processes to form CZTS films.

### Example 20

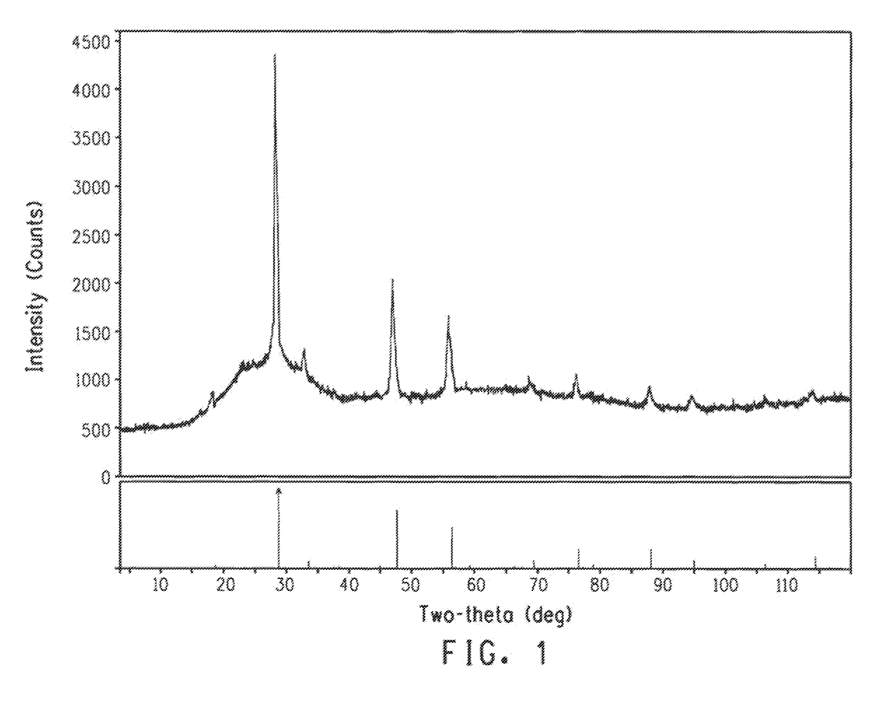

A CZTS precursor-coated substrate obtained by the process described in Example 15 was annealed in a tube furnace at 500° C. for 2 hr in a sulfur/N₂ atmosphere. The sulfur/N₂ atmosphere was created by having elemental sulfur near the N₂ gas inlet in the tube furnace during annealing. XRD results obtained after the annealing step show that the Cu₂SnS₃ and ZnS precursors were converted to CZTS. The XRD data obtained after heating are shown in FIG. 1.

### Example 21

A CZTS precursor-coated substrate obtained by the process described in Example 17 was annealed in a tube furnace at 500° C. for 30 min under a sulfur/N₂ atmosphere.

### Example 22

A CZTS precursor-coated substrate obtained by the process described in Example 18 was annealed at 700° C. for 30 min under a sulfur/N₂ atmosphere. The XRD data showed CZTS formation after annealing.

### Example 23

This example illustrates the formation of CZTS/Se films in a selenium-rich atmosphere.

A CZTS precursor-coated substrate is obtained by the process described in Example 15 was annealed at 500° C. for 30 min under a selenium/N₂ atmosphere. The atmosphere was achieved by having elemental selenium and the sample in a closed but not sealed container in the furnace tube and at the same time having a constant nitrogen flow through the furnace tube.

### Example 24

A CZTS precursor-coated substrate is obtained by the process described in Example 15 is annealed at 500° C. for 30 min under a H₂S/N₂ atmosphere. The H₂S/N₂ atmosphere is achieved by flowing a mixture of H₂S and N₂ gases through the tube furnace.

### Example 25

A CZTS precursor-coated substrate obtained by the process described in Example 19 is annealed in a tube furnace at 500° C. for 2 hr in a sulfur/N₂ atmosphere.

### Examples 26-28

Examples 26-28 illustrate the preparation of photovoltaic cells incorporating an absorber layer derived from CZTS precursor inks.

### General

Substrates for photovoltaic cells were prepared by coating a soda lime glass with 500 nm of molybdenum using a Denton Sputtering System under the deposition conditions of 150 W DC power, 20 sccm argon and 5 mT pressure.

These photovoltaic cell substrates were used for the deposition of CZTS precursor inks, which were then annealed to form CZTS films. CdS was deposited on the CZTS films (as described below in Examples 26-28), followed by the deposition of a transparent conductor with the structure of 50 nm of insulating ZnO (150 W RF, 5 m Torr, 20 sccm) and 500 nm of Al-doped ZnO. A 2% Al₂O₃, 98% ZnO target (75 W RF, 10 mTorr, 20 sccm) was used for the sputter deposition of Al-doped ZnO.

### Example 26

A p-type CZTS film was formed on a photovoltaic cell substrate according to the process described in Example 14. The photovoltaic cell was then placed in a CdS bath and 50 nm of n-type CdS was deposited on top of the CZTS film.

The CdS bath solution was prepared by mixing water (28.92 mL), 28% ammonium hydroxide (5.15 mL), 0.015 mol/L cadmium sulfate solution (3.95 mL), and 1.5 mol/L thiourea (1.98 mL). The CZTS-coated photovoltaic cell substrates were submerged in the bath solution and the temperature was increased from room temperature to 65° C. in a water-heated vessel. After 11 min, the samples were taken out and rinsed with de-ionized water for an hour and then dried at 200° C. for 15 min.

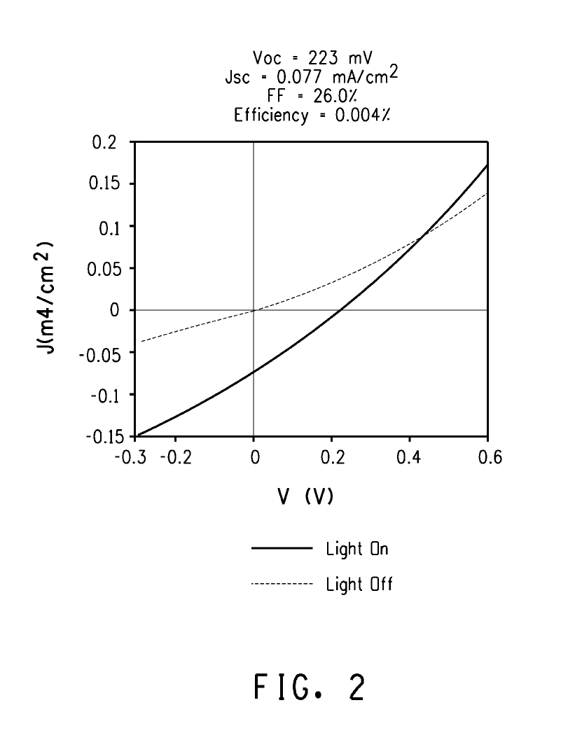

After deposition of CdS and a transparent conductor, the performance of the finished devices was tested under 1 sun illumination. The resulting J-V curves are shown in FIG. 2.

### Example 27

A p-type CZTS film was formed on a photovoltaic cell substrate according to the process described in Example 14. The photovoltaic cell was then placed in a CdS bath and 50 nm of n-type CdS was deposited on top of the CZTS film.

The CdS bath solution was prepared by mixing cadmium iodide (0.2747 g) and concentrated aqueous ammonia (49 mL) to preheated water (191 mL) at 65° C. in a polytetrafluoroethylene (PTFE) beaker. A CZTS film-coated photovoltaic cell substrate was placed in a PTFE beaker containing the cadmium iodide solution. A solution of thiourea (5.7090 g) in 10 mL water was added to the PTFE beaker containing the substrate, and CdS was allowed to deposit for 5 min. The coated substrate was removed from the bath, rinsed with water and then soaked for 1 h in 18.2 MΩ water. The substrate was then annealed for 2 min at 250° C. and left in a vacuum desicator overnight.

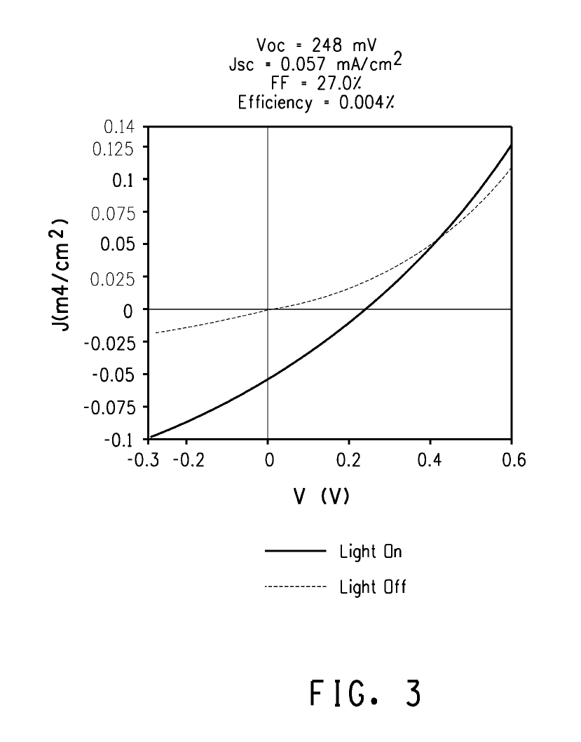

The performance of the finished device was tested under 1 sun illumination and the resulting J-V curves are shown in FIG. 3.

### Example 28

A p-type CZTS film was formed on a photovoltaic cell substrate according to the process described in Example 20. The sample was then placed in a CdS bath and 50 nm of n-type CdS was deposited on top of the CZTS film.

The CdS bath precursor solution was prepared by mixing 34.846 mL H₂O, 12.4 mg CdSO₄, 225.6 mg thiourea, and 5.15 mL 28% NH₄OH. The temperature was increased from room temperature to 65° C. After 9 min of deposition, the substrate was removed from the bath, rinsed with water, and then soaked for 1 h in 18.2 MΩ water. The coated substrate was then annealed for 2 min at 250° C.

A transparent conducting layer was then deposited on the CdS layer, and the performance of the finished device tested under 1 sun illumination.

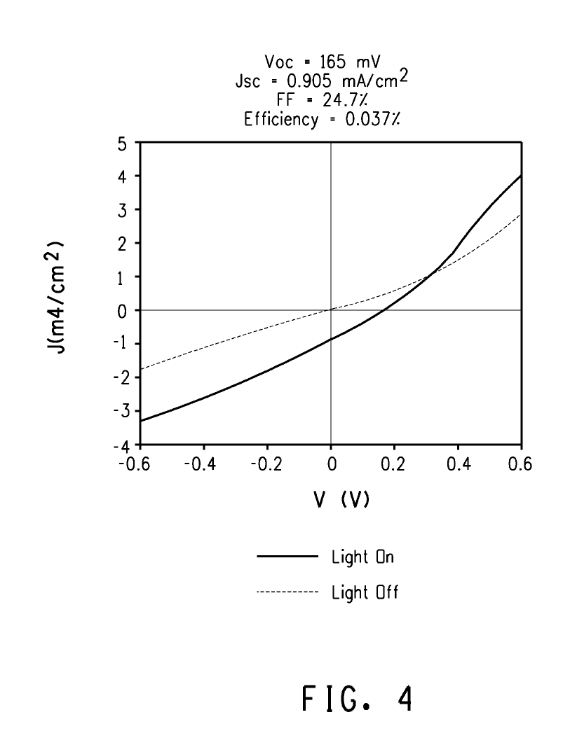

The resulting J-V curves are shown in FIG. 4.

What is claimed is:

1. A composition comprising:
a) a fluid medium;
b) coated copper-containing chalcogenide nanoparticles;
c) coated tin-containing chalcogenide nanoparticles; and
d) coated zinc-containing chalcogenide nanoparticles,
wherein the chalcogenide is a sulfide or selenide and the molar ratio of Cu:Zn:Sn:(S+Se) of the composition is about 2:1:1:4.

2. The composition of claim 1, wherein the copper-containing chalcogenide is selected from the group consisting of Cu₂S, CuS, Cu₂Se, CuSe, Cu₂SnS₃, Cu₄SnS₄, and Cu₂SnSe₃.

3. The composition of claim 1, wherein the tin-containing chalcogenide is selected from the group consisting of SnS₂, SnS, SnSe, SnSe₂, Cu₂SnS₃, Cu₄SnS₄, and Cu₂SnSe₃.

4. The composition of claim 1, wherein the zinc-containing chalcogenide is ZnS or ZnSe.

5. The composition of claim 1, wherein the coated copper-containing chalcogenide nanoparticles comprise an organic stabilizing agent selected from the group consisting of alkyl amines, alkyl thiols, trialkylphosphine oxide, trialkylphosphines, alkylphosphonic acids, polyvinylpyrrolidone, polycarboxylates, polyphosphates, polyamines, pyridine, alkylpyridines, peptides comprising cysteine and/or histidine residues, ethanolamines, citrates, thioglycolic acid, oleic acid, and polyethylene glycol.

6. The composition of claim 1, wherein the coated tin-containing chalcogenide nanoparticles comprise an organic stabilizing agent selected from the group consisting of alkyl amines, alkyl thiols, trialkylphosphine oxide, trialkylphosphines, alkylphosphonic acids, polyvinylpyrrolidone, polycarboxylates, polyphosphates, polyamines, pyridine, alkylpyridines, peptides comprising cysteine and/or histidine residues, ethanolamines, citrates, thioglycolic acid, oleic acid, and polyethylene glycol.

7. The composition of claim 1, wherein the coated zinc-containing chalcogenide nanoparticles comprise a an organic stabilizing agent selected from the group consisting of alkyl amines, alkyl thiols, trialkylphosphine oxide, trialkylphosphines, alkylphosphonic acids, polyvinylpyrrolidone, polycarboxylates, polyphosphates, polyamines, pyridine, alkylpyridines, peptides comprising cysteine and/or histidine residues, ethanolamines, citrates, thioglycolic acid, oleic acid, and polyethylene glycol.

8. The composition of claim 1, wherein the fluid medium is selected from the group consisting of toluene, chloroform, dichloromethane, pyridine, hexane, heptane, octane, acetone, 2-butanone, methyl ethyl ketone, water, and alcohol.

9. The composition of claim 1, further comprising an additive up to 1 wt %, based on the total weight of the composition, wherein the additive is a sodium salt, elemental sulfur or elemental selenium.

10. A process comprising dispersing in a fluid medium a mixture comprising:
a) coated copper-containing chalcogenide nanoparticles;
b) coated tin-containing chalcogenide nanoparticles; and
c) coated zinc-containing chalcogenide nanoparticles, wherein the chalcogenide is a sulfide or selenide and the molar ratio of Cu:Zn:Sn:(S+Se) of the composition is about 2:1:1:4.

11. The process of claim 10, wherein the fluid medium is selected from the group consisting of toluene, chloroform, dichloromethane, pyridine, hexane, heptane, octane, acetone, 2-butanone, methyl ethyl ketone, water, and alcohol.

12. A process comprising depositing a dispersion onto a substrate, wherein the dispersion comprises:
a) a fluid medium;
b) coated copper-containing chalcogenide nanoparticles;
c) coated tin-containing chalcogenide nanoparticles; and
d) coated zinc-containing chalcogenide nanoparticles, wherein the chalcogenide is a sulfide or selenide and the molar ratio of Cu:Zn:Sn:(S+Se) of the composition is about 2:1:1:4.

13. The process of claim 12, wherein the fluid medium is selected from the group consisting of toluene, chloroform, dichloromethane, pyridine, hexane, heptane, octane, acetone, 2-butanone, methyl ethyl ketone, water, and alcohol.

14. The process of claim 12, wherein the substrate is selected from the group consisting of glass, metal, or polymer substrates; molybdenum-coated soda lime glass; molybdenum-coated polyimide films; and molybdenum-coated polyimide films further comprising a layer of a sodium compound.

15. The process of claim 12, further comprising removing the fluid medium to form a coated substrate.

16. The process of claim 15, wherein the chalcogenide is a sulfide and the process further comprises heating the coated substrate to form a CZTS film on the substrate.

17. The process of claim 15, wherein the chalcogenide is a selenide and the process further comprises heating the coated substrate to form a CZTSe film on the substrate.

18. The process of claim 15, wherein the chalcogenide is a mixture of a sulfide and a selenide and the process further comprises heating the coated substrate to form a CZTS/Se film on the substrate.

19. A process for forming photovoltaic cells comprising:
a) coating a photovoltaic cell substrate with a composition comprising:
i) a fluid medium;
ii) coated copper-containing chalcogenide nanoparticles;
iii) coated tin-containing chalcogenide nanoparticles; and
iv) coated zinc-containing chalcogenide nanoparticles,
wherein the chalcogenide is a sulfide or selenide and the molar ratio of Cu:Zn:Sn:(S+Se) of the composition is about 2:1:1:4 to form a coated substrate;
b) heating the coated photovoltaic cell substrate at a temperature between 400° C. and 600° C. to form an annealed CZTS/Se thin film on the photovoltaic cell substrate;
c) optionally repeating steps a) and b) to form a CZTS/Se film of the desired thickness;
d) depositing a buffer layer onto the CZTS/Se layer; and
e) depositing a top contact layer onto the buffer layer.
